(19) United States
(12) Patent Application Publication
(10) Pub. No.: US 2008/0213927 A1
(43) Pub. Date: Sep. 4, 2008

(54) METHOD FOR MANUFACTURING AN IMPROVED RESISTIVE STRUCTURE

(75) Inventors: Maria Wang, Plano, TX (US); Erika Leigh Shoemaker, Richardson, TX (US); Mary Roby, Plano, TX (US); Stuart Jacobsen, Frisco, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/681,556

(22) Filed: Mar. 2, 2007

(51) Int. Cl. H01L 21/62; H01L 21/4763

(52) U.S. Cl. 438/21; 438/384; 257/E21.006

(57) ABSTRACT

Provided, in one embodiment, is a method for manufacturing a resistive structure. This method, without limitation, includes forming a substrate, and forming a tantalum-aluminum-nitride resistive layer over the substrate. Moreover, a bulk resistivity of the tantalum-aluminum-nitride resistive layer may be adjusted by varying at least one deposition condition selected from the group consisting of a flow rate ratio of nitrogen to argon, power, pressure, temperature and radio frequency (RF) bias voltage.

### TECHNICAL FIELD OF THE INVENTION

The invention relates to resistive layers and in particular to a method for manufacturing an improved resistive structure.

### BACKGROUND OF THE INVENTION

Micro-fluid ejection devices such as ink jet printers continue to experience wide acceptance as economical replacements for laser printers. Micro-fluid ejection devices also are finding wide application in other fields such as in the medical, chemical, and mechanical fields. As the capabilities of micro-fluid ejection devices are increased to provide higher ejection rates, the ejection heads, which are the primary components of micro-fluid devices, continue to evolve and become more complex. As the complexity of the ejection heads increases, so does the cost for producing ejection heads. Nevertheless, there continues to be a need for micro-fluid ejection devices having enhanced capabilities including increased quality and higher throughput rates. Competitive pressure on print quality and price promote a continued need to produce ejection heads with enhanced capabilities in a more economical manner.

### SUMMARY OF THE INVENTION

With regard to the foregoing and other objects and advantages there is provided a method for manufacturing a resistive structure. This method, without limitation, includes forming a substrate, and forming a tantalum-aluminum-nitride resistive layer over the substrate. Moreover, a bulk resistivity of the tantalum-aluminum-nitride resistive layer may be adjusted by varying at least one deposition condition selected from the group consisting of a flow rate ratio of nitrogen to argon, power, pressure, temperature and radio frequency (RF) bias voltage.

In yet another embodiment, a method for manufacturing an electrical contact is provided. The method for manufacturing the electrical contact, among other steps, may include forming an opening within an insulative layer, the opening exposing a conductive structure located therebelow, and forming a tantalum-aluminum-nitride barrier layer along sidewalls of the opening. This method may further include forming a conductive plug over the tantalum-aluminum-nitride barrier layer and within the opening.

### BRIEF DESCRIPTION OF THE DRAWINGS

Further advantages of the invention will become apparent by reference to the detailed description of exemplary embodiments when considered in conjunction with the following drawings illustrating one or more non-limiting aspects of the invention, wherein like reference characters designate like or similar elements throughout the several drawings as follows:

FIG. 1 is a micro-fluid ejection device cartridge, not to scale, containing a micro-fluid ejection head according to one embodiment;

FIG. 2 is a perspective view of an ink jet printer and ink cartridge containing a micro-fluid ejection head according to one embodiment;

FIG. 3 is a cross-sectional view, not to scale of a portion of a micro-fluid ejection head according to one embodiment;

FIG. 4 is a plan view not to scale of a typical layout on a substrate for a micro-fluid ejection head according to one embodiment;

FIG. 5 is a plan view, not to scale of a portion of an active area of a micro-fluid ejection head according to one embodiment;

FIG. 6 is a cross-sectional view of a heater stack area of a micro-fluid ejection head according to one embodiment; and

FIG. 7 is a cross-sectional view of a semiconductor device including a heater resistor and one or more metal oxide semiconductor (MOS) devices.

### DETAILED DESCRIPTION

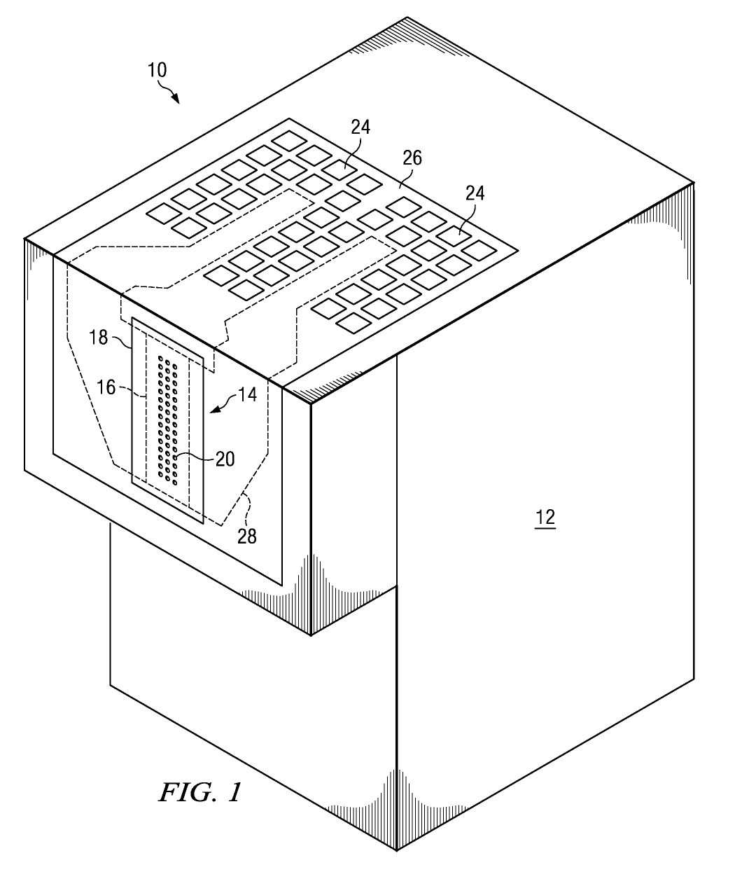

With reference to FIG. 1, a fluid cartridge 10 for a micro-fluid ejection device is illustrated. The cartridge 10 includes a cartridge body 12 for supplying a fluid to a fluid ejection head 14. The fluid may be contained in a storage area in the cartridge body 12 or may be supplied from a remote source to the cartridge body.

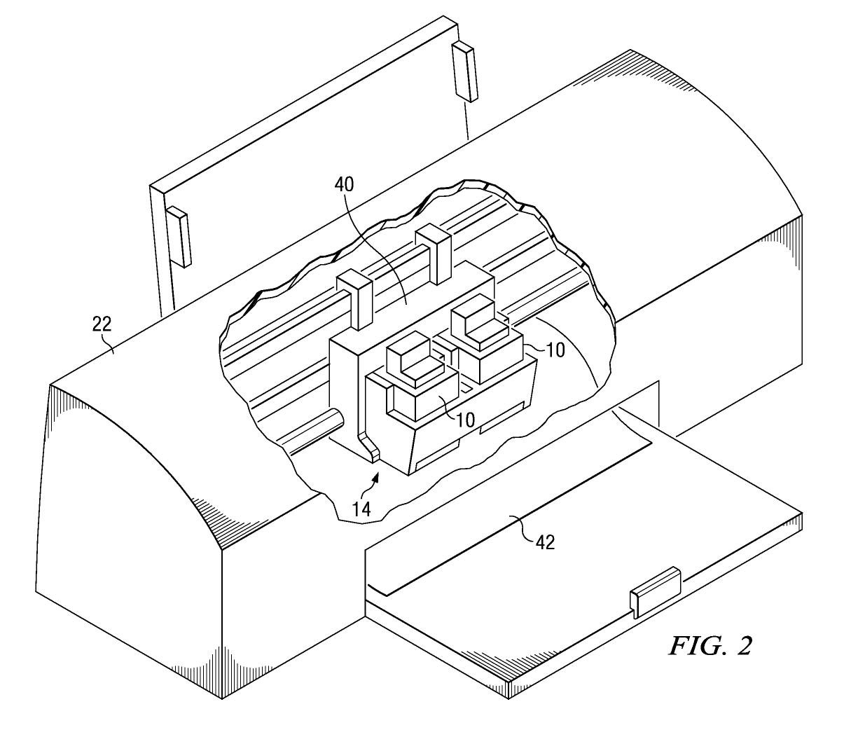

The fluid ejection head 14 includes a semiconductor substrate 16 and a nozzle plate 18 containing nozzle holes 20. In one embodiment, it is preferred that the cartridge be removably attached to a micro-fluid ejection device such as an ink jet printer 22 (FIG. 2). Accordingly, electrical contacts 24 are provided on a flexible circuit 26 for electrical connection to the micro-fluid ejection device. The flexible circuit 26 includes electrical traces 28 that are connected to the substrate 16 of the fluid ejection head 14.

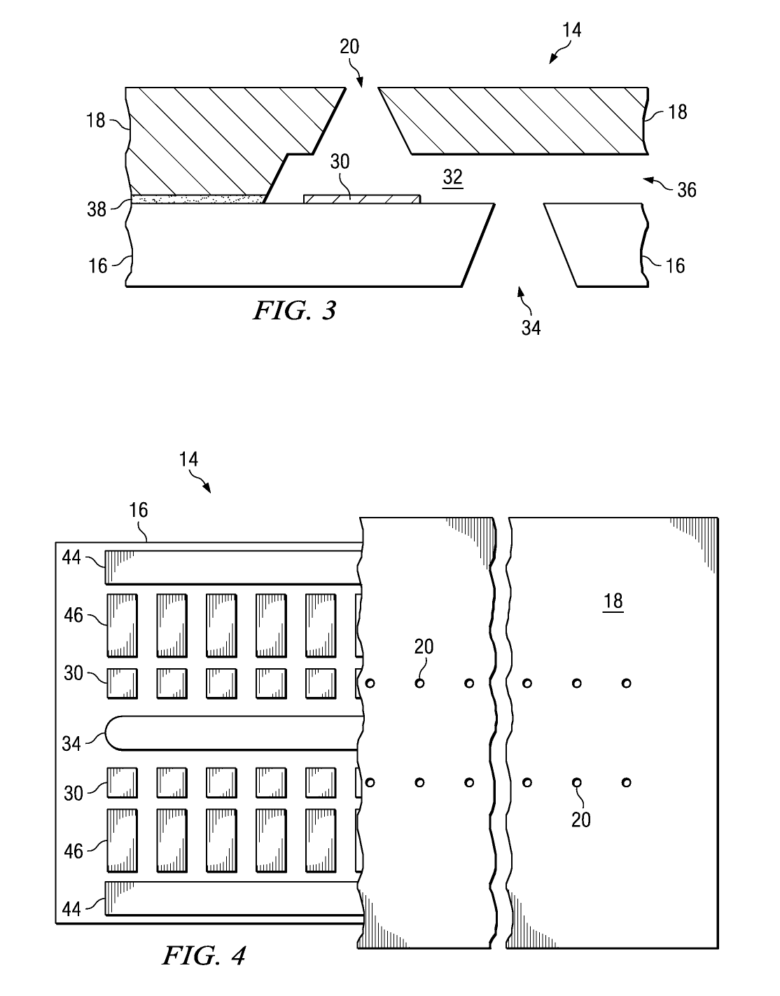

An enlarged cross-sectional view, not to scale, of a portion of the fluid ejection head 14 is illustrated in FIG. 3. In one embodiment, the fluid ejection head 14 preferably contains a thermal heating element 30 (e.g., a heater chip) as a fluid ejection actuator for heating the fluid in a fluid chamber 32 formed in the nozzle plate 18 between the substrate 16 and a nozzle hole 20. The thermal heating elements 30 are resistors which, in one embodiment, are comprised of an alloy of tantalum, aluminum, nitrogen, as described in more detail below.

Fluid is provided to the fluid chamber 32 through an opening or slot 34 in the substrate 16 and through a fluid channel 36 connecting the slot 34 with the fluid chamber 32. The nozzle plate 18 can be adhesively attached to the substrate 16, such as by adhesive layer 38. As depicted in FIG. 3, the flow features including the fluid chamber 32 and fluid channel 36 can be formed in the nozzle plate 18. However, the flow features may be provided in a separate thick film layer, and a nozzle plate containing only nozzle holes may be attached to the thick film layer. In one embodiment, the fluid ejection head 14 is a thermal or piezoelectric ink jet printhead. However, the disclosure is not intended to be limited to ink jet printheads, as fluids other than ink may be ejected with a micro-fluid ejection device.

Referring again to FIG. 2, the fluid ejection device can be an ink jet printer 22. The printer 22 includes a carriage 40 for holding one or more cartridges 10 and for moving the cartridges 10 over a media 42, such as paper, and thus depositing a fluid from the cartridges 10 on the media 42. As set forth above, the contacts 24 on the cartridge mate with contacts on the carriage 40 for providing electrical connection between the printer 22 and the cartridge 10. Microcontrollers in the printer 22 control the movement of the carriage 40 across the media 42 and convert analog and/or digital inputs from an external device, such as a computer, for controlling the operation of the printer 22. Ejection of fluid from the fluid ejection head 14 is controlled by a logic circuit on the fluid ejection head 14 in conjunction with the controller in the printer 22.

A plan view, not to scale, of a fluid ejection head 14 is shown in FIG. 4. The fluid ejection head 14 includes a semiconductor substrate 16 and a nozzle plate 18 attached to the substrate 16. A layout of device areas of the semiconductor substrate 16 is shown providing locations for logic circuitry 44, driver transistors 46, and heater resistors 30. As shown in FIG. 4, the substrate 16 includes a single slot 34 for providing fluid, such as ink, to the heater resistors 30 that are disposed on both sides of the slot 34. However, the invention is not limited to a substrate 16 having a single slot 34 or to fluid ejection actuators such as heater resistors 30 disposed on both sides of the slot 34. For example, other substrates may include multiple slots with fluid ejection actuators disposed on one or both sides of the slots. The substrate 16 may also not include slots 34, whereby fluid flows around the edges of the substrate 16 to the actuators. Rather than a single slot 34, the substrate 16 may include multiples or openings, one each for one or more actuator devices. The nozzle plate 18, such as one made of an ink resistant material such as polyimide, is attached to the substrate 16.

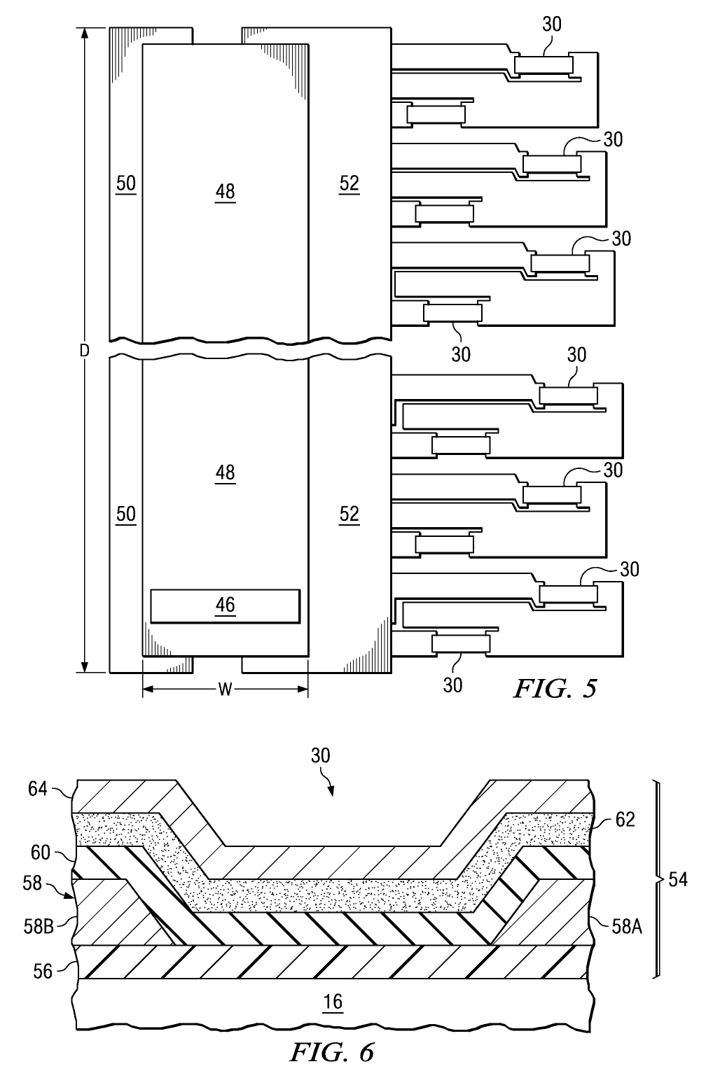

An active area 48 of the substrate 16 required for the driver transistors 46 is illustrated in detail in a plan view of the active area 48 in FIG. 5. This figure represents a portion of a typical heater array and active area 48. A ground bus 50 and a power bus 52 are provided to provide power to the devices in the active area 46 and to the heater resistors 30.

In order to reduce the size of the substrate 16 required for the micro-fluid ejection head 14, the driver transistor 46 active area width indicated by (W) is reduced. In one embodiment, the active area 48 of the substrate 16 has a width dimension W ranging from about 100 to about 400 microns and an overall length dimension D ranging from about 6,300 microns to about 26,000 microns. The driver transistors 46 are provided at a pitch P ranging from about 10 microns to about 84 microns.

In one embodiment, the area of a single driver transistor 46 in the semiconductor substrate 16 has an active area width (W) ranging from about 100 to less than about 400 microns, and an active area of, for example, less than about 15,000 μm². The smaller active area 46 can be achieved by use of driver transistors 46 having gates lengths and channel lengths ranging from about 0.8 to less than about 3 microns.

However, the resistance of the driver transistor 46 is proportional to its width W. The use of smaller driver transistors 46 increases the resistance of the driver transistor 46. Thus, in order to maintain a constant ratio between the heater resistance and the driver transistor resistance, the resistance of the heater 30 can be increased proportionately. A benefit of a higher resistance heater 30 can include that the heater requires less driving current. In combination with other features of the heater 30, one embodiment of the invention provides an ejection head 14 having higher efficiency and a head capable of higher frequency operation.

There are several ways to provide a higher resistance heater 30. One approach is to use a higher aspect ratio heater, that is, a heater having a length significantly greater than its width. However, such high aspect ratio design tends to trap air in the fluid chamber 32. Another approach to providing a high resistance heater 30 is to provide a heater made from a thin film having a higher sheet resistance. One such material is TaAl. However, relatively thin TaAl has inadequate aluminum barrier characteristics thereby making it less suitable than other materials for use in micro-fluid ejection devices. Aluminum barrier characteristics can be particularly important when the resistive layer is extended over and deposited in a contact area for an adjacent transistor device. Without a protective layer, for example TiW, in the contact area, the thin film TaAl is insufficient to prevent diffusion between aluminum deposited as the contact metal and the underlying silicon substrate.

A heater, according to one embodiment, is a thin film heater 30 made of an alloy of tantalum, aluminum, and nitrogen. In contrast to the thin film TaAl heater described above, a thin film heater 30 made according to such an embodiment can also provide a suitable barrier layer in an adjacent transistor contact (e.g., electrical contact) area without the use of an intermediate barrier layer between the aluminum contact and silicon substrate, as well as provide a higher resistance heater 30.

The thin film heater 30 can be provided by sputtering a tantalum/aluminum alloy target onto a substrate 16 in the presence of nitrogen and argon gas. In one embodiment, the tantalum/aluminum alloy target preferably has a composition ranging from about 40 to about 60 atomic percent tantalum and from about 40 to about 60 atomic percent aluminum. In another embodiment, the resulting thin film heater 30 has a composition ranging from about 20 to about 70 atomic % tantalum, from about 20 to about 40 atomic % aluminum and from about 5 to about 40 atomic % nitrogen. The bulk resistivity of the thin film heaters 30 according to an exemplary embodiment preferably ranges from about 100 to about 3000 micro-ohms-cm.

In order to produce a TaAlN heater 30 having the characteristics described above, suitable sputtering conditions are desired. For example, specific sputtering conditions may be used to adjust the bulk resistivity of the TaAlN heater 30. Namely, the bulk resistivity of the TaAlN heater 30 (e.g., tantalum-aluminum-nitride resistive layer) is adjusted by varying at least one deposition condition selected from the group consisting of a flow rate ratio of nitrogen to argon, power, pressure, temperature and radio frequency (RF) bias voltage. For example, in one embodiment, the substrate 16 can be heated to above room temperature to about 600° C., more preferably from about 100° C. to about 400° C., during the sputtering step. Also, the nitrogen to argon gas flow rate ratio, the sputtering power and the gas pressure are preferably within relatively narrow ranges. In one exemplary process, the nitrogen to argon flow rate ratio ranges from about 0.05:1 to about 0.4:1. In this embodiment, the nitrogen may be distributed within the deposition chamber using a gas distribution ring. The use of the gas distribution ring allows the nitrogen to react with the argon plasma around substantially the entire, if not the entire, wafer during the sputtering. Furthermore, in one embodiment the sputtering power ranges from about 1.0 to about 10 kilowatts and the pressure ranges from about 0.5 to about 30 millitorrs. Additionally, an RF bias voltage of between about 0 volts and about 600 volts might be used.

Heaters 30 made according to the foregoing process exhibit a relatively uniform sheet resistance over the surface area of the substrate 16 ranging from about 30 to about 600 ohms per square. The sheet resistance of the thin film heater 30 may have a standard deviation over the entire substrate surface of less than about 5 percent, preferably less than about 2 percent. Such a uniform resistivity significantly improves the quality of ejection heads 14 containing the heaters 30. The heaters 30 made according to the foregoing process can tolerate high temperature stress up to about 800° C. with a resistance change of less than about 5 percent. The heaters 30 made according to such an embodiment can also tolerate high current stress. Additionally, heaters 30 manufactured as described may have a bulk resistivity ranging from about 100 micro-ohm-cm to about 3000 micro-ohm-cm, among others. Also, unlike TaAlN resistors made by sputtering bulk tantalum and aluminum targets on room temperature substrates, such as described in U.S. Pat. No. 4,042,479 to Yamazaki et al., the thin film heaters 30 made according to such an embodiment may be characterized as having a substantially mono-crystalline structure consisting essentially of AlN, TaN, and TaAl alloys. By using TaAlN as the material for the heater resistor 30, the layer providing the heater resistor 30 may be extended to provide a metal barrier for contacts to adjacent transistor devices and may also be used as a fuse material on the substrate 16 for memory devices and other applications.

A more detailed illustration of a portion of an ejection head 14 showing an exemplary heater stack 54 including a heater 30 made according to the above described process is illustrated in FIG. 6. The heater stack 54 is provided on an insulated substrate 16. First layer 56 is the resistive layer made of TaAlN which is deposited on the substrate 16 according to a process similar to that described above.

After depositing the resistive layer 56, a conductive layer 58 made of a conductive metal such as gold, aluminum, copper, and the like may be deposited on the resistive layer 56. The conductive layer 58 may have any suitable thickness known to those skilled in the art, but, in an exemplary embodiment, preferably has a thickness ranging from about 0.1 to about 1.2 microns. After deposition of the conductive layer 58, the conductive layer may be etched to provide anode 58A and cathode 58B contacts to the resistive layer 56 and to define the heater resistor 30 therebetween the anode and cathode 58A and 58B.

A passivation layer or dielectric layer 60 can then be deposited on the heater resistor 30 and anode and cathode 58A and 58B. The layer 60 may be selected from diamond like carbon, doped diamond like carbon, silicon oxide, silicon oxynitride, silicon nitride, silicon carbide, and a combination of silicon nitride and silicon carbide. In an exemplary embodiment, a particularly preferred layer 60 is diamond like carbon having a thickness ranging from about 50 to about 500 nanometers.

When a diamond like carbon material is used as layer 60, an adhesion layer 62 can be deposited on layer 60. The adhesion layer 62 may be selected from silicon nitride, silicon carbide, tantalum nitride, titanium nitride, tantalum oxide, and the like. In an exemplary embodiment, the thickness of the adhesion layer preferably ranges from about 10 to about 300 nanometers.

After depositing the adhesion layer 62, in the case of the use of diamond like carbon as layer 60, a cavitation layer 64 can be deposited and etched to cover the heater resistor 30. An exemplary cavitation layer 64 is tantalum having a thickness ranging from about from about 100 to about 800 nanometers.

It is desirable to keep the passivation or dielectric layer 60, optional adhesion layer 62, and cavitation layer 64 as thin as possible yet provide suitable protection for the heater resistor 30 from the corrosive and mechanical damage effects of the fluid being ejected. Thin layers 60, 62, and 64 can reduce the overall thickness dimension of the heater stack 54 and provide reduced power requirements and increased efficiency for the heater resistor 30.

Once the cavitation layer 64 is deposited, this layer 64 and the underlying layer or layers 60 and 62 may be patterned and etched to provide protection of the heater resistor 30. A second dielectric layer made of silicon dioxide can then be deposited over the heater stack 54 and other surfaces of the substrate to provide insulation between subsequent metal layers that are deposited on the substrate for contact to the heater drivers and other devices.

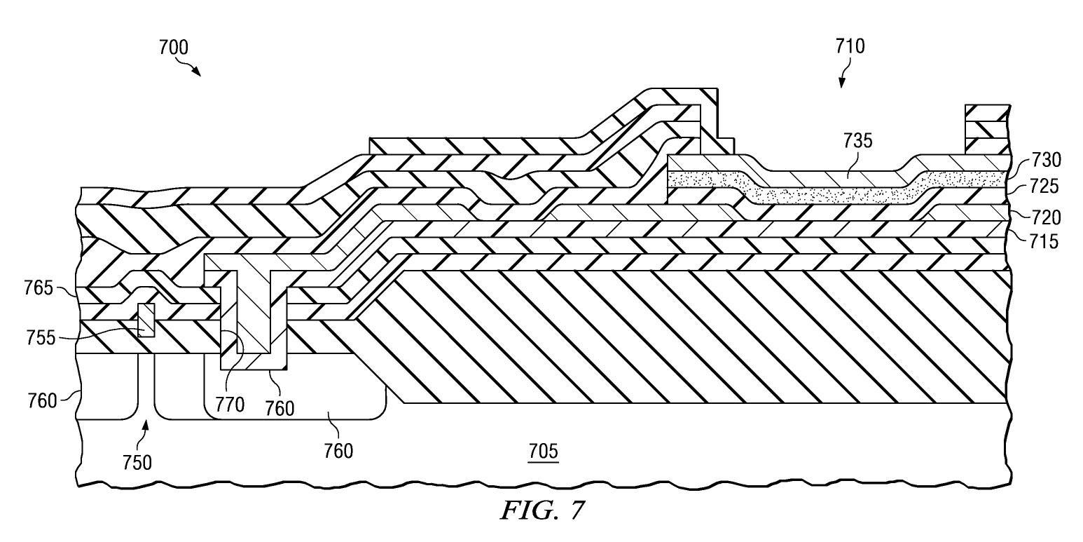

FIG. 7 illustrates a semiconductor device 700 including a heater resistor 710 and one or more metal oxide semiconductor (MOS) devices 750. The heater resistor 710, in one embodiment, may be similar to the heater resistor 30 illustrated in FIG. 6. The heater resistor 710 includes a resistive layer 715 manufactured according to one embodiment of this disclosure. For instance, the resistive layer 715 could be manufactured using similar processes as those described above for the resistive layer 56. Located over the resistive layer 715 is a patterned conductive layer 720, dielectric layer 725, optional adhesion layer 730 and the cavitation layer 735. The patterned conductive layer 720, dielectric layer 725, optional adhesion layer 730 and the cavitation layer 735 may be similar to the conductive layer 58, dielectric layer 60, optional adhesion layer 62 and the cavitation layer 64, respectively, described above.

The MOS device 750, in the illustrative embodiment, includes a gate structure 755 located over a substrate 705, and source/drain regions 760 located in the substrate 705. Additionally, one or more insulative layers 765 may be located over the MOS device 750. In the embodiment shown, an opening 770 exists within the one or more insulative layers 765. The resistive layer 715, in this embodiment, is located within the opening 770 and electrically contacts at least one of the source/drain regions 760 of the MOS device 750. Additionally, the conductive layer 720 (e.g., a copper plug in one embodiment) is located within the opening 770 and over the resistive layer 715. In the embodiment shown in FIG. 7, the resistive layer 715, which may comprise the tantalum-aluminum-nitride material, may act as a diffusion barrier between the conductive layer 720 and the source/drain region 760.

It is contemplated, and will be apparent to those skilled in the art from the preceding description and the accompanying drawings, that modifications and changes may be made in the embodiments of the invention. Accordingly, it is expressly intended that the foregoing description and the accompanying drawings are illustrative of exemplary embodiments only, not limiting thereto, and that the true spirit and scope of the present invention be determined by reference to the appended claims.

What is claimed is:

1. A method for manufacturing a resistive structure, comprising:
forming a substrate; and
forming a tantalum-aluminum-nitride resistive layer over the substrate, wherein a bulk resistivity of the tantalum-aluminum-nitride resistive layer is adjusted by varying at least one deposition condition selected from the group consisting of a flow rate ratio of nitrogen to argon, power, pressure, temperature and radio frequency (RF) bias voltage.

2. The method of claim 1 wherein the flow rate ratio is varied to adjust the bulk resistivity.

3. The method of claim 2 wherein the flow rate ratio ranges from about 0.05:1 to about 0.4:1.

4. The method of claim 1 wherein the power is varied to adjust the bulk resistivity.

5. The method of claim 4 wherein the power ranges from about 1.0 kilowatts to about 10 kilowatts.

6. The method of claim 1 wherein the pressure is varied to adjust the bulk resistivity.

7. The method of claim 6 wherein the pressure ranges from about 0.5 mtorr to about 30 mtorr.

8. The method of claim 1 wherein forming a tantalum-aluminum-nitride resistive layer includes sputter depositing the tantalum-aluminum-nitride resistive layer.

9. The method of claim 1 wherein forming a tantalum-aluminum-nitride resistive layer includes distributing the nitrogen through a gas distribution ring in a deposition chamber.

10. The method of claim 1 further including forming a conductive layer over the tantalum-aluminum-nitride resistive layer and etching the conductive layer to define an anode and a cathode connection to the tantalum-nitride resistive layer.

11. The method of claim 10 wherein the tantalum-aluminum-nitride resistive layer is located within an opening in an insulative layer and electrically contacts a source/drain region of a metal oxide semiconductor device, and further wherein the conductive layer is located within the opening and over the tantalum-aluminum-nitride resistive layer.

12. The method of claim 11 wherein the tantalum-aluminum-nitride resistive layer acts as a diffusion barrier layer between the conductive layer and the source/drain region.

13. The method of claim 1 wherein the bulk resistivity ranges from about 100 micro-ohm-cm to about 3000 micro-ohm-cm.

14. The method of claim 1 wherein forming a tantalum-aluminum-nitride resistive layer includes forming a tantalum-aluminum-nitride resistive layer containing from about 20 to about 70 atomic % tantalum, from about 20 to about 40 atomic % aluminum and from about 5 to about 40 atomic % nitrogen.

15. The method of claim 1 wherein forming a tantalum-aluminum-nitride resistive layer includes forming a tantalum-aluminum-nitride resistive layer consisting essentially of AlN, TaN and TaAl, or alloys thereof.

16. The method of claim 1 wherein the tantalum-aluminum-nitride resistive layer forms at least a portion of a fuse.

17. The method of claim 1 wherein the temperature is varied between about room temperature and about 400° C. to adjust the bulk resistivity.

18. The method of claim 1 wherein the radio frequency (RF) bias voltage is varied between about 0 volts and 600 volts.

19. A method for manufacturing an electrical contact, comprising:
forming an opening within an insulative layer, the opening exposing a conductive structure located therebelow;
forming a tantalum-aluminum-nitride barrier layer along sidewalls of the opening; and
forming a conductive plug over the tantalum-aluminum-nitride barrier layer and within the opening.

20. The method of claim 19 wherein the conductive structure is a source/drain region for a metal oxide semiconductor device.
